(19) United States
(12) Patent Application Publication
(10) Pub. No.: US 2013/0306148 A1
(43) Pub. Date: Nov. 21, 2013

(54) METHOD FOR FABRICATING SUBSTRATE FOR SOLAR CELL AND SOLAR CELL

(71) Applicants: Hidetaka Takato, Ibaraki (JP); Isao Sakata, Ibaraki (JP); Keiji Mase, Tokyo (JP); Shozo Ishibashi, Tokyo (JP); Takayuki Harada, Tokyo (JP); Yoichi Kondo, Fukuoka (JP); Hideyuki Asai, Fukuoka (JP)

(72) Inventors: Hidetaka Takato, Ibaraki (JP); Isao Sakata, Ibaraki (JP); Keiji Mase, Tokyo (JP); Shozo Ishibashi, Tokyo (JP); Takayuki Harada, Tokyo (JP); Yoichi Kondo, Fukuoka (JP); Hideyuki Asai, Fukuoka (JP)

(73) Assignee: FUJI MANUFACTURING CO., LTD., Tokyo (JP)

(21) Appl. No.: 13/982,104

(22) PCT Filed: Jan. 27, 2012
(86) PCT No.: PCT/JP2012/051783

§ 371 Date: Aug. 7, 2013

(30) Foreign Application Priority Data
Jan. 31, 2011 (JP) 2011-019092

(51) Int. Cl. H01L 31/0236

(52) U.S. Cl. CPC H01L 31/02363
USPC 136/258; 438/691

(57) ABSTRACT

The problem addressed by the present invention is providing a technique for fabricating, by a method simpler than conventional methods, a silicon substrate that is effective for light trapping, one surface of which has a textured structure and the other surface of which has higher reflectivity than the surface having the textured structure. The fabrication method for this semiconductor substrate comprises: a sandblasting step in which a first surface of a silicon substrate in an as-sliced state, fabricated by slicing a silicon ingot, is surface treated by sandblasting and, after the sandblasting step, a step for carrying out surface treatment using an etching solution that contains either or both of hydrofluoric acid and nitric acid on the silicon substrate.

### FIELD OF THE INVENTION

The present invention relates to a method for forming a textured structure of a silicon substrate for manufacture of a crystalline silicon solar cell, and solar cell using the substrate.

### DESCRIPTION OF THE RELATED ARTS

The high efficiency and the price reduction of crystalline silicon solar cells using monocrystalline silicon substrates and polycrystalline silicon substrates are important for the spread of solar cells.

For efficiency improvement of solar cells, a method to confine incident light in a substrate effectively (optical confinement) by making a substrate surface uneven structure (textured structure), by reducing light reflectance of a solar cell surface and by lengthening optical paths in the substrate, is widely used. In this case, from an efficiency improvement standpoint, it is not necessary that the textured structures are formed on both surfaces of the silicon substrate. Rather, it is desirable that the textured structure be formed only on one surface of the substrate and the other surface be a minor surface having higher reflectance than that with the textured structure (Non-Patent Document 1).

By the way, crystalline silicon substrates which are generally used for crystalline silicon solar cells at present are formed by a method to slice a silicon ingot with a multi-wire saw using an abrasive gram-containing cutting fluid and piano wires (loose abrasive grain system). Silicon substrates in an as-sliced state which are formed by the loose abrasive grain method have random irregularities and damaged layer produced on surfaces thereof.

In the case of polycrystalline silicon substrates, although the difference in plane orientation between each in-plane crystal grain poses problem of difficulty in forming uniform texture in plane, use of the damaged layer enables formation of the texture which is less influenced by the plane orientations of crystal grains. Specifically, a method to form the textured structure of the substrate surface while removing the damaged layer of the polycrystalline silicon substrates in an as-sliced state by using an isotropic etching solution which contains hydrofluoric acid and nitric acid, is widely used (Non-Patent Document 2).

However, by this method, the textured structures are formed on both surfaces of the silicon substrates. This is because the substrates sliced with the loose abrasive grain system have the above-mentioned random irregularities and damaged layers resulting in easy formation of the textures with the solution on both surfaces of the silicon substrates. Therefore, in order that the textured structure is formed only on one surface of the substrates while the other surface has higher reflectance than that with the textured structure hi the substrates sliced with the loose abrasive grain system, it has been necessary to etch again the surface whose reflectance will be made higher with a different etching solution from that for the texture formation.

Moreover, as another method of texture formation, Patent Document 1 discloses a method to use plasma instead of the solution. However, the method presents a problem of high cost because vacuum apparatuses must be used.

Furthermore, Patent Document 2 discloses a method for forming a textured structure by forming damaged layer on an entire silicon substrate with wire slicing and sandblasting (See FIG. 2 of Patent Document 2). then forming the textured structure by dipping the substrate into an acid solution, rinsing die substrate, and then dipping the substrate into an alkaline solution. However, the Patent Document 2 does not describe reflectance of silicon substrates in an as-sliced state and reflectance of front faces and reverse faces of the silicon substrates after the texture formation.

On the other hand, as a method to slice a silicon ingot, it is discussed to slice an ingot with a multi-wire saw using a fixed abrasive grain wire (diamond wire) made by fixing diamond abrasive grains to piano wires with electrodeposition, resin, metal or combinations thereof (fixed abrasive grain system) (Non-Patent Document 3). In comparison with the loose abrasive grain system, this system is characterized by a small used amount of the wires, more than double slicing speed and few problems of liquid waste disposal due to use of a coolant which does not contain abrasive grains. Thus, the use of this system enables reduction in the slicing cost. Therefore, the method to slice an ingot with the fixed abrasive grain system is expected as a next-generation slicing technique.

### DOCUMENTS OF RELATED ART

### Patent Documents

Patent Document 1: IP 2003-101051 A

Patent Document 2: JP 2005-340643 A

### Non-Patent Documents

Non-Patent Document 1: J. Rentsch et. al., “Single side etching-key technology for industrial high efficiency processing”, 23rd European Photovoltaic Solar Energy Conference, Valencia, P. 1889, September, 2008,

Non-Patent Document 2: A. Hauser et. al., “Acidic texturisation mc-Si using a high throughput in-line prototype system which no organic chemistry”, 19th European Photovoltaic Solar Energy Conference, Paris, p. 1094, June, 2004.

Non-Patent Document 3: T. Aoyama et. al, “Fabrication of single-crystalline silicon solar cells using wafers sliced by a diamond wire saw”, 5th World Conference on Photovoltaic Energy Conversion, Valencia, September, 2010.

### DISCLOSURE OF THE INVENTION

### Problem to be Solved by the Invention

The present invention has been made in view of the above-mentioned situation, and aims to provide a technique for forming, by a method simpler than conventional methods, a silicon substrate which is effective for optical confinement, one surface of which has textured structure and the other surface of which has a surface with higher reflectance than that of the textured structure.

### Means for solving the Problems

Through, extensive research, the inventors have found that the method to slice an ingot with the fixed abrasive grain system has a characteristic of, by selecting conditions of the slice suitably, being able to provide higher reflectance on a surface of silicon substrates in an as-sliced state sliced by the slicing method. Moreover, the inventors have found that a surface of the silicon substrate in an as-sliced state sliced with the fixed abrasive grain system has a characteristic of not being subject to formation of textured structure by etching with a solution, in comparison with the surface of the silicon substrate hi an as-sliced state sliced with the loose abrasive grain system. The inventors have reached the present invention by finding these characteristics.

Therefore, the present invention has the following configuration.

A method for forming a semiconductor substrate according to the present invention comprises:
a sandblasting step in which surface treatment by sandblasting is performed on a first surface of a silicon substrate in an as-sliced state formed by slicing a silicon ingot; and
a surface treatment step with an etching solution containing one or more of hydrofluoric acid and nitric acid, performed on the silicon substrate after the sandblasting step.

According to the above-mentioned configuration, in the method for forming the semiconductor substrate of the present invention, the first surface may comprise more in-plane damaged layer with a surface profile which is suitable for formation of textured structure than a surface opposite to the first surface due to the surface treatment by sandblasting. Then, in the etching treatment with a solution, the more uniformly in-plane damaged layer with a surface profile which is suitable for formation of textured structure is present in fixed depth, the more easily textured structure is formed on the surface. According to the above-mentioned configuration, the surface treatment with an etching solution is performed to silicon substrates with such surfaces varying in ease of formation of textured structure.

Therefore, according to the above-mentioned configuration, textured structure can be formed only on the first surface by the surface treatment with an etching solution without distinguishing the first surface and the opposite surface, by using difference in ease of formation of textured structure between the first surface and the opposite surface. Thus the method for forming semiconductor substrates of the present invention can provide a technique for forming, by the method simpler than conventional methods, a silicon substrate which is effective for optical confinement, one surface of which has textured structure and the other surface of which has higher reflectance than that with textured structure.

According to another aspect of the present invention, the method for forming a semiconductor substrate may further comprises a slicing step for forming the silicon substrate by slicing a silicon ingot, wherein the first surface and a second surface opposite to the first surface of the silicon substrate have 28% to 36% reflectance to light within the wavelength range of 600 nm to 800 nm. and the silicon substrate in an as-sliced state may be formed through the slicing step.

Here, 28% to 36% reflectance is relatively high among the reflectance of conventional silicon substrate surfaces in an as-sliced state.

Therefore, according to the above-mentioned configuration, more efficient silicon substrates can be formed by the method simpler than conventional methods.

According to another aspect of the present invention, the slicing step may be performed by using a wire with fixed abrasive grain grams, which is made by fixing diamond abrasive grains to a surface of a metal wire by a method with electrodeposition. resin, metal or combinations thereof.

As described above, in the slicing method with the fixed abrasive grain system, suitable selection of slicing conditions can provide higher reflectance on the surface of the silicon substrate in an as-sliced state sliced by the slicing method.

Therefore, according to the above-mentioned configuration, the reflectance of the first and second surfaces in an as-sliced state can be made higher.

Moreover, as described above, textured structure is poorly formed by etching with a solution on the surface of the silicon substrate in an as-sliced state sliced with the fixed abrasive grain system, in comparison with the surface of the silicon substrate in an as-sliced state sliced with the loose abrasive grain system.

Therefore, according to the above-mentioned configuration, difference in ease of formation of textured structure between the first surface and the second surface can be made more predominant. Thus, in the above-mentioned etching treatment for performing the surface treatment with an etching solution, textured structure can be more easily formed only on the first surface.

According to another aspect of the present invention, in the surface treatment step with an etching solution, the surface treatment may be performed simultaneously on the first surface and the second surface of the silicon substrate with the etching solution.

As described above, textured structure is more easily formed on the first surface than the second surface. Therefore, even if the surface treatment is performed simultaneously on the first surface and the second surface with the etching solution as the above-mentioned configuration, textured structure can be formed only on the first surface.

Thus, since the etching can be performed without distinguishing the first surface and the second surface, the above-mentioned configuration can provide a technique for forming. by the method simpler than conventional methods, a silicon substrate which is effective for optical confinement, one surface of which has textured structure and the other surface of which has higher reflectance than that with textured structure.

According to another aspect of the present invention, the silicon ingot may be polycrystalline silicon.

According to another aspect of the present invention, a solar cell may be formed by using the semiconductor substrate formed by each method for forming the semiconductor substrate described above.

According to the above-mentioned configuration, since silicon substrates can be formed by the method simpler than conventional methods, solar cells can be formed by a method simpler than conventional methods. Moreover, because the use of the silicon substrates enhances the optical confinement effect and BSF (Back Surface Field) effect, more efficient crystalline silicon solar cells can be formed by the same conventional processes.

### EFFECTS OF THE INVENTION

The present invention can provide a technique for forming, by the method simpler than conventional methods, a silicon substrate which is effective for optical confinement, one surface of which has textured structure and the other surface of which has higher reflectance than that with textured structure.

### BRIEF DESCRIPTION OF THE DRAWINGS

FIG. 1A is a photograph of a surface condition of a silicon substrate sliced with a fixed abrasive grain system;

FIG. 1B is a photograph of a surface condition of a silicon substrate sliced with a loose abrasive grain system;

FIG. 2 is a graph showing the comparison of surface reflectance between the silicon substrate sliced with the fixed abrasive grain system and the silicon substrate sliced with the loose abrasive grain system;

FIG. 3 is a photograph showing a condition of a surface treated by sandblasting of the silicon substrate sliced with the fixed abrasive grain system;

FIG. 4A is a photograph of a first surface (textured surface) of the silicon substrate obtained in an example of the present invention:

FIG. 4B is a photograph of a second surface of the silicon substrate obtained in the example of the present invention; and

FIG. 5 is a graph showing the comparison of surface reflectance between the first surface (textured surface) and the second surface of the silicon substrate obtained in the example of the present invention.

### BEST MODE FOR CARRYING OUT THE INVENTION

Hereinafter, an embodiment of a method for forming silicon substrates for solar cells according to an aspect of the present invention (hereinafter, also referred to as “the present embodiment”) will be described.

At the outset, a silicon ingot is sliced with a multi-wire saw using fixed abrasive grain wires (diamond wires) to form silicon substrates hi an as-sliced state (hereinafter, the silicon substrate is also simply referred to as “substrate”). In this case, as the fixed abrasive grain wire, wire made by fixing diamond abrasive grains to metal wire with electrodeposition, resin, metal or combinations thereof is used. Also, the silicon ingot used in the present embodiment is a polycrystalline silicon ingot, but a monocrystalline silicon ingot may be used.

Moreover, if. is required that a surface of sliced silicon substrates in an as-sliced state keeps reflectance of light (hereinafter, also referred to as “surface reflectance”) as high as possible. In the present embodiment, it is required that the reflectance of both surfaces of the sliced silicon substrates in an as-sliced state is 28% to 36%, preferably 30% to 36% to all light within the wavelength range of 600 nm to 800 nm. If the reflectance is less than 28%. it is nearly the same as surface reflectance of substrates in an as-sliced state sliced by a loose abrasive grain method. On the other hand, the upper limit of the reflectance is 36%. This is because reflectance of monocrystalline silicon substrates in a minor surface state is a maximum of around 36% to light within the wavelength range of 600 nm to 800 nm (Phys.Rev., Vol. 120, p.37 (1960)). Since the reflectance of silicon substrates in a mirror surface state is a maximum of 36% to light within the wavelength range of 600 nm to 800 nm, the upper limit of the surface reflectance of the silicon substrates according to the present embodiment is 36%.

The condition of the slice with the fixed abrasive grain wire for determining the

reflectance of the silicon substrates within the above-mentioned range depend on factors such as a diameter of the fixed abrasive grain wire, a particle diameter of the diamond abrasive grains and a slicing speed. Therefore, it is necessary for operators to examine the slicing conditions for meeting requirement for the above-mentioned surface reflectance by an experiment or the like beforehand. For example, when a silicon ingot is sliced with the fixed abrasive grain wire in order that silicon substrates in an as-sliced state have a thickness of around 100 μm to 200 μm and a size of 156 mm square, it is desirable that a diameter of the fixed abrasive grain wire be 90 μm to 160 μm, particle diameters of the diamond abrasive grains be 5 μm to 30 μm and the slicing speed be about 0.2 mm/min to 1.5 mm/min.

Next, only one surface of the silicon substrates is treated by sandblasting to form damaged layer on the surface uniformly. The condition of the sandblasting (a type of abrasive, a size of abrasive, ejection pressure of abrasives) is not particularly limited as long as the surface treated by sandblasting has enough depth direction and in-plane uniformity to be uniformly etched in plane in the subsequent etching step.

However, it is desirable that the type of abrasive be silicon carbide (SiC), alumina oxide, emery or garnet. Moreover, it is preferable that the abrasive have a particle size of #400 to #3000. Furthermore, it is preferable that the ejection pressure of the abrasives be 0.2 MPa to 0.6 MPa. A system of the sandblasting does not include only a system to eject the abrasives with gas such as air or nitrogen but may include a system to eject a mixture of abrasives and water. The surface treated by sandblasting corresponds to a first surface of the present invention.

Furthermore, after the sandblasting, by etching the silicon substrates with a solution containing one or more of hydrofluoric acid and nitric acid, desired substrates can be obtained.

The reason can be explained as follows. The surface treated by sandblasting includes more in-plane damaged layer with a surface profile which is suitable for formation of textured structure uniformly than a surface not treated by sandblasting. In the etching treatment with the solution, the more uniformly in-plane damaged layer with a surface profile which is suitable for formation of textured structure is present in fixed depth, the more easily textured structure is formed on the surface. Thus, in the etching treatment with the solution, the textured structure is formed more easily on the surface treated by sandblasting than that not treated by sandblasting. Using the ease of formation of textured structure enables the formation of textured structure on the surface treated by sandblasting and precludes the formation of textured structure on the other surface not treated by sandblasting. As a result, silicon substrates which are effective for optical confinement, one surface of which has textured structure and the other surface of which has higher reflectance than that with textured structure can be formed.

The damaged layer is poorly formed on a surface of silicon substrates in an as-sliced state sliced with the fixed abrasive grain method, in comparison with a surface of silicon substrates in an as-sliced state sliced with the loose abrasive grain system. Thus, with the fixed abrasive grain system, textured structure is more poorly formed than the loose abrasive grain system on a surface not treated with sandblasting by etching with the solution. Therefore, in order to more clarify difference in ease of formation of textured structure by etching with the solution, the fixed abrasive grain system is effective.

The etching may be performed by a method to immerse the silicon substrates in the etching solution or a method to spray the etching solution on the silicon substrates with a shower or the like.

As an example for etching silicon substrates, there is a method to immerse the silicon substrates in an etching solution containing hydrofluoric acid and nitric acid, temperature of winch is maintained in a range of 5° C. to 30° C., then rinsing the silicon substrates. Depending on conditions, during this etching treatment, a brown-black porous layer is sometimes formed on a surface of the silicon substrates, hi this case, it is necessary that, after rinsing, the silicon substrates are immersed in an alkaline solution such as several percent (e.g., 1% to 3%) of sodium hydroxide solution to remove the porous layer. Alternatively, the etching may be performed with a solution made by adding an additive to prevent formation of the porous layer to the above-mentioned solution containing hydrofluoric acid and nitric acid.

Accordingly, even if the etching treatment is performed simultaneously on both surfaces of the substrates instead of several etching treatments, silicon substrates which are effective for optical confinement, one surface of which has textured structure and the other surface of which has higher reflectance than that with textured structure can be formed. Therefore, in the method for forming silicon substrates according to the present embodiment, since the etching treatment is once off and need not be performed several times, silicon substrates with the above-mentioned structure which are effective for optical confinement can be formed more simply and at a lower cost than conventional methods.

### EXAMPLE

Hereinafter, an example of the present embodiment will be described, but the present invention is not limited to the following example.

In order to obtain a silicon substrate in an as-sliced state having relatively higher reflectance, a polycrystalline silicon ingot was sliced with multi-wire saw using fixed abrasive grain wires (diamond wires). The wire was made by fixing diamond abrasive grains to a metal wire with a resin bond, and diameter of the wire was about 150 μm. Moreover, the slicing speed was 0.5 mm/min. Further, the thickness of a sliced polycrystalline silicon substrate was about 200 μm.

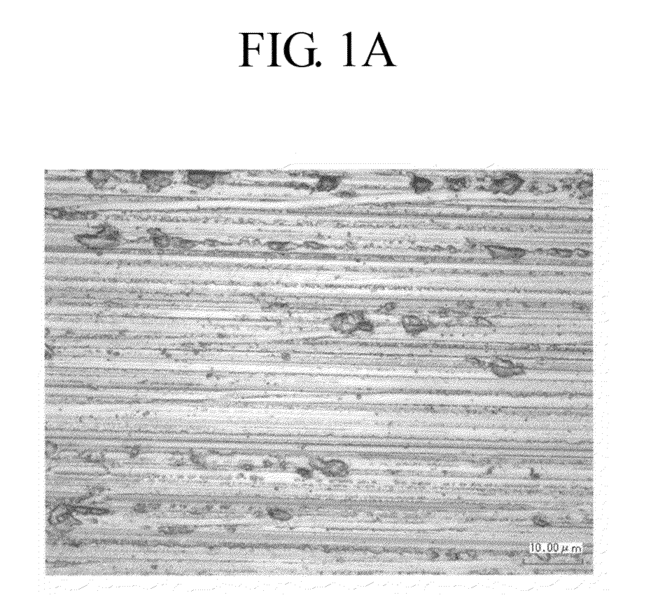

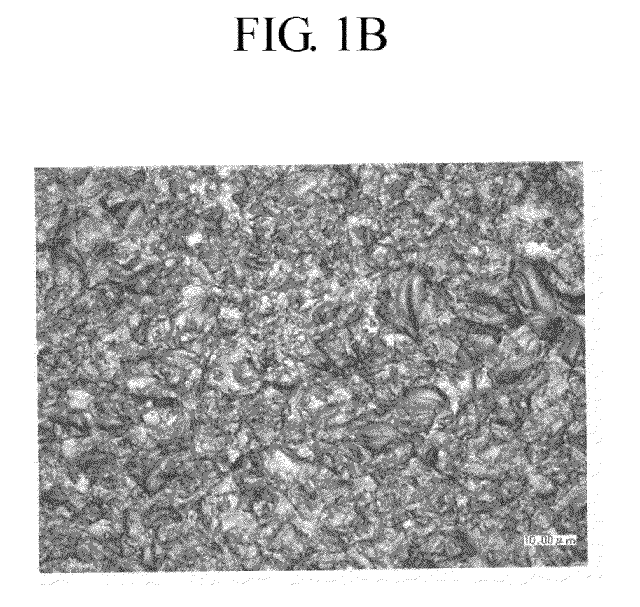

FIG. 1A is a photograph of a surface of a polycrystalline silicon substrate in an as-sliced state sliced with the fixed abrasive grain system using the fixed abrasive grain wire. Furthermore, FIG. 1B is a photograph of a surface of a polycrystalline silicon substrate in an as-sliced state sliced with the loose abrasive grain system. As shown in FIGS. 1A and 1B, surface profiles of the silicon substrates greatly vary depending on the slicing systems.

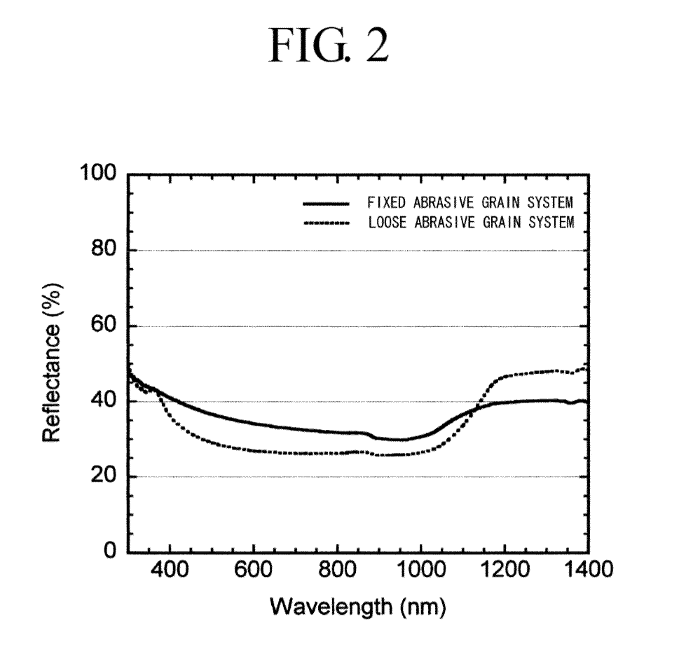

Moreover, FIG. 2 shows reflectance of these silicon substrates in an as-sliced state. The measurement was performed with a spectrophotometer (Hitachi spectrophotometer U4000) using an integrating sphere. To light within the wavelength range of 600 nm to 800 nm, the reflectance on the surface of the substrate sliced with the fixed abrasive grain system is between 32% and 34%, whereas the reflectance on the surface of the substrate sliced with the loose abrasive grain system is between 26% and 27%. Thus, depending on the surface conditions, the reflectance of the substrate sliced with the fixed abrasive grain system is higher than that of the substrate sliced with the loose abrasive grain system. Therefore, it was proven that, in the fixed abrasive grain system, a silicon substrate having higher reflectance than a substrate surface sliced with the loose abrasive grain system could be formed by selecting suitable slicing conditions.

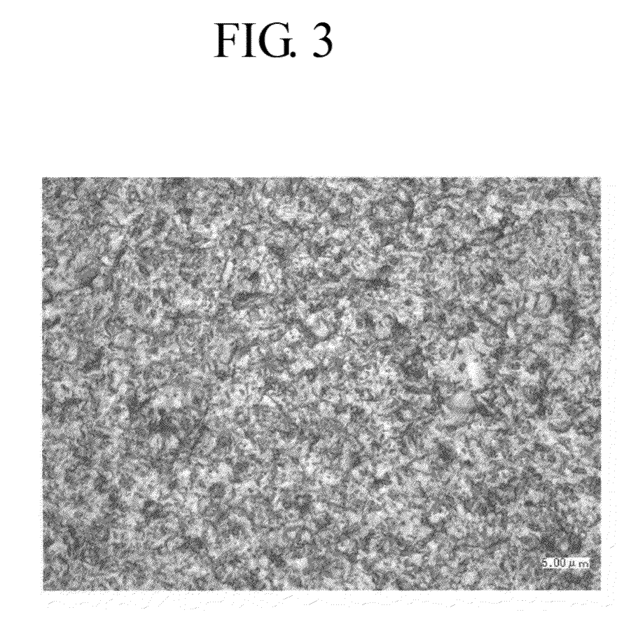

Then, sandblasting was performed only on one surface of the silicon substrate. FIG. 3 shows a surface condition of the substrate treated by sandblasting. In the present example, the sandblasting was performed by ejecting abrasives with air, by use of PNEUMA-BLASTER (TM) SG-4 (manufactured by Fuji Manufacturing Co., Ltd.). The type of abrasives used was Fujilundum WA (manufactured by Fuji Manufacturing Co., Ltd.), the abrasives had a particle size of #1000 (average particle diameter of 11 μm) and the ejection pressure of the abrasives was 0.3 MPa. As shown in FIG. 3, a streaky pattern peculiar to substrates sliced with the fixed abrasive grain system was disappeared by sandblasting, and damaged layer was formed on the surface uniformly.

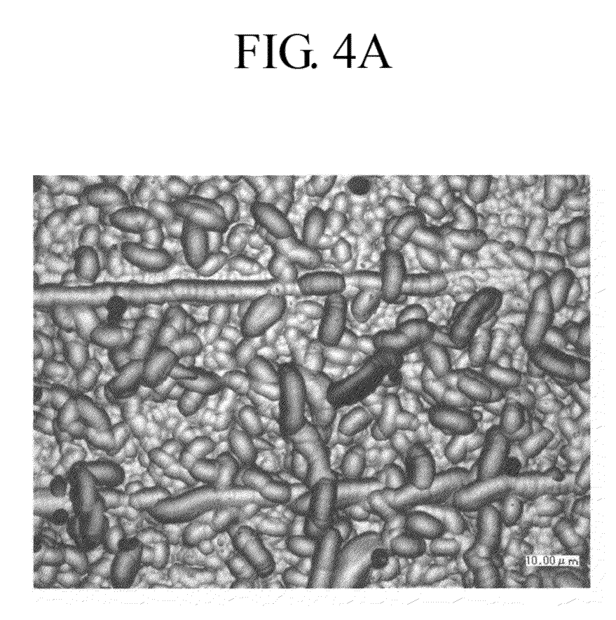

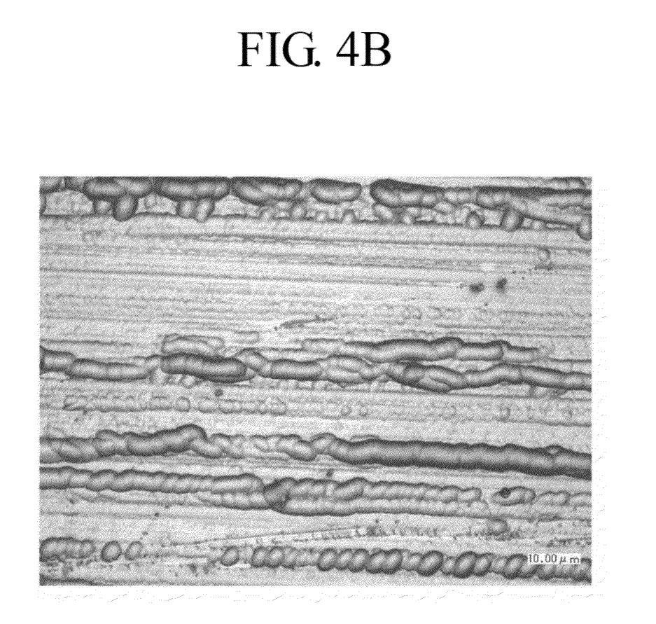

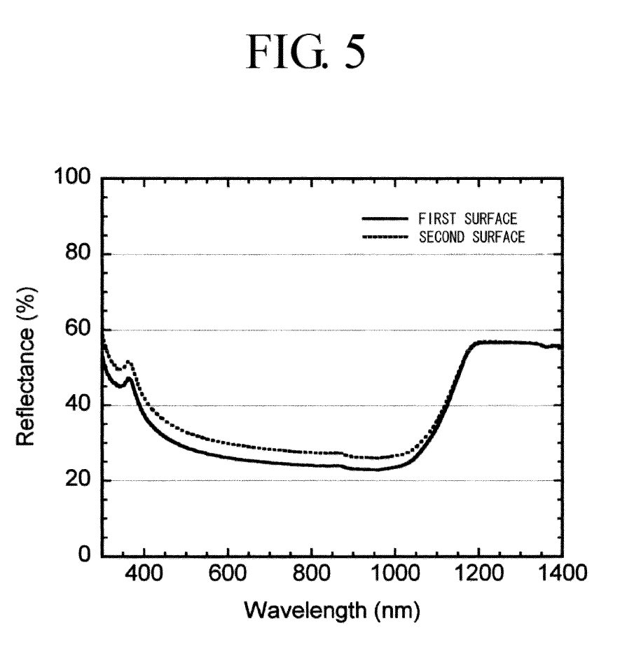

Next, isotropic etching was performed on the substrate with an acid etching solution. In the present example, the etching was performed with a mixed solution which had a hydrofluoric acid/nitric acid volume ratio in the solution of 7:5, by immersing the substrate for about 100 seconds in the etching solution maintained at 20° C. FIG. 4A is a photograph of a surface obtained after performing etching treatment on the surface treated by sandblasting (hereinafter, referred to as “first surface”). Further, FIG. 4B is a photograph of a surface obtained after perforating etching treatment on the surface not treated by sandblasting (hereinafter, referred to as “second surface”). On the first surface, textured structure was formed on the whole area of the substrate and the effectiveness of the sandblasting; was observed. However, on the second surface not treated by sandblasting, although textured profile formed by etching performed with the solution was observed, the streaky pattern which had existed before etching was still observed, hence the textured structure was not formed clearly in comparison with the first surface. FIG. 5 shows reflectance of the first surface and the second surface of the silicon substrate. On the above-mentioned first surface, low reflectance was observed to light within a wide wavelength range, and the reflectance to light within the wavelength range of 600 nm to 800 nm was between 24% and 26%. However, on the above-mentioned second surface, it was observed that the reflectance was lower than the surface in an as-sliced state before etching treatment while it was higher than the first surface by about 3.5% in the absolute value.

As described above, in the present example, by using the method for forming silicon substrates according to the present embodiment, the silicon substrate which was effective for optical confinement, one surface of which had textured structure and the other surface of which had higher reflectance than that with textured structure could be obtained through one etching treatment.

1. A method for forming a semiconductor substrate comprising:
a sandblasting step in which surface treatment by sandblasting is performed on a first surface of a silicon substrate in an as-sliced state formed by slicing a silicon ingot; and
a surface treatment step with an etching solution containing one or more of hydrofluoric acid and nitric acid, performed on the silicon substrate after the sandblasting step.

2. The method for forming a semiconductor substrate according to claim 1, further comprising a slicing step for forming the silicon substrate by slicing a silicon ingot, wherein the first surface and a second surface opposite to the first surface of the silicon substrate have 28% to 36% reflectance to light within the wavelength range of 600 nm to 800 nm, and
the silicon substrate in an as-sliced state is formed through the slicing step.

3. The method for forming a semiconductor substrate according to claim 2, wherein the slicing step is performed by using a wire with fixed abrasive grain grains, the wire being made by fixing diamond abrasive grains to a surface of a metal wire by a method with electrodeposition, resin, metal or combinations thereof.

4. The method for forming a semiconductor substrate according to claim 2, wherein, in the surface treatment step with the etching solution, the surface treatment is performed simultaneously on the first surface and the second surface of the silicon substrate with the etching solution.

5. The method for forming a semiconductor substrate according to any one of the preceding claim 1, wherein the silicon ingot is polycrystalline silicon.

6. A solar cell formed by using the semiconductor substrate formed by the method for forming the semiconductor substrate according to claim 1.

7. The method for forming a semiconductor substrate according to claim 3, wherein, in the surface treatment step with the etching solution, the surface treatment is performed simultaneously on the first surface and the second surface of the silicon substrate with the etching solution.

8. The method for forming a semiconductor substrate according to claim 2, wherein the silicon ingot is polycrystalline silicon.

9. The method for forming a semiconductor substrate according to claim 3, wherein the silicon ingot is polycrystalline silicon.

10. The method for forming a semiconductor substrate according to claim 4, wherein the silicon ingot is polycrystalline silicon.

11. The method for forming a semiconductor substrate according to claim 5, wherein the silicon ingot is polycrystalline silicon.

12. A solar cell formed by using the semiconductor substrate formed by the method for forming the semiconductor substrate according to claim 2.

13. A solar cell formed by using the semiconductor substrate formed by the method for forming the semiconductor substrate according to claim 3.

14. A solar ceil formed by using the semiconductor substrate formed by the method for forming the semiconductor substrate according to claim 4.

15. A solar cell formed by using the semiconductor substrate formed by the method for forming the semiconductor substrate according to claim 5.

16. A solar cell formed by using the semiconductor substrate formed by the method for forming the semiconductor substrate according to claim 6.

17. A solar ceil formed by using the semiconductor substrate formed by the method for forming the semiconductor substrate according to claim 7.

18. A solar cell formed by using the semiconductor substrate formed by the method for forming the semiconductor substrate according to claim 8.

19. A solar cell formed by using the semiconductor substrate formed by the method for forming the semiconductor substrate according to claim 9.

20. A solar ceil formed by using the semiconductor substrate formed by the method for forming the semiconductor substrate according to claim 10.
